(19) United States
(12) Patent Application Publication
(10) Pub. No.: US 2005/0202601 A1
(43) Pub. Date: Sep. 15, 2005

(54) Electro-optical device, method of manufacturing the same, and electronic apparatus

(75) Inventor: Shin Koide, Suwa-shi (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 11/037,141

(22) Filed: Jan. 19, 2005

(30) Foreign Application Priority Data
Mar. 15, 2004 (JP) 2004-072684

(51) Int. Cl. G02F 1/136; H01L 21/84

(52) U.S. Cl. 438/149

(57) ABSTRACT

To control transistor the characteristics and the manufacturing efficiency of TFTs for driving display elements in an active manner and for realizing a display with high definition and high brightness. There is provided a method of manufacturing an electro-optical device comprising a step of forming a semiconductor film on a base, a step of forming a dummy film to cover the semiconductor film, a first injection step of injecting a first injection amount of an impurity into the semiconductor film via the dummy film to form a lightly doped region, a second injection step of injecting a second injection amount of an impurity into the semiconductor film via the dummy film to form a source region and a drain region, a step of removing the dummy film, a step of forming a gate insulating film, and a step of forming a gate electrode in a region on the gate insulating film overlapping at least a portion of a channel region and the lightly doped region.

### BACKGROUND

The present invention relates to an electro-optical device such as a liquid crystal device, a method of manufacturing the same, and to an electronic apparatus, such as a liquid crystal projector, having the electro-optical device.

As such an electro-optical device, an active matrix drive type electro-optical device in which a display element of each pixel is driven in an active manner by means of a thin film transistor (hereinafter, referred to as “TFT”) is known. In such an electro-optical device, as the TFT, for example, one having a self alignment type LDD (Lightly Doped Drain) structure is used. Such a TFT is formed with, for example, a low-temperature polysilicon film for every pixel, together with various driving elements such as a storage capacitor.

In order to realize a display with high brightness and high definition, there is a problem with the OFF current of the TFT in each pixel which must be addressed. In the TFT, when the tunneling effects in a junction of a drain are dominant, the OFF current is caused. In this case, by forming the film thickness of a gate insulating film of the TFT large, it is possible to reliably reduce the OFF current.

Here, in the case of manufacturing a self alignment type TFT, an impurity is injected into a semiconductor film via a gate insulating film with a gate electrode serving as a mask, to thus form a lightly doped region, a source region and a drain region. Meanwhile, at the time of making the film thickness of the gate insulating film large, an ion injection is performed with higher energy. However, by performing the ion injection with high energy, the ion energy is converted into heat, which consequently heats and distorts the substrate. In particular, when a resist is used as a mask, an adverse effect that the resist is deteriorated due to heating is caused. Thus, the film thickness of the gate insulating film is limited to the extent that such an adverse effect is prevented.

Meanwhile, in Patent Document 1, a manufacturing method of a TFT having a gate overlap type LDD structure (GOLD structure) is disclosed. In the TFT having the GOLD structure, it is possible to further increase an ON current, as compared to the TFT having the self alignment type LDD structure. Further, according to Patent Document 1, an ion injection is performed while covering a channel region in the semiconductor film with the resist serving as the mask. Thus, a lightly doped region, a source region and a drain region are formed in the semiconductor film, and then a gate insulating film is formed on the semiconductor film. According to this method, it is possible to form the gate insulating film with a desired film thickness.

[Patent Document 1] Japanese Unexamined Patent Application Publication No. 11-330487.

### SUMMARY

However, according to the method disclosed in Patent Document 1, impurity is directly injected into the semiconductor film. Thus, with respect to a concentration distribution, the concentration of the impurity tends to increase at a position deeper than the vicinity of the surface of the semiconductor film. Therefore, according to the manufacturing method of Patent Document 1, there is a problem in that the semiconductor film having a poor conductivity in the vicinity of the surface is manufactured.

Meanwhile, in the case of injecting the impurity into the semiconductor film via the gate insulating film, if the film is thick and the injection energy is high, there is an adverse effect caused by the substrate heating. Further, if the film is thin and the injection energy is low, the temperature of the substrate does not rise, and thus the impurity does not react with the silicon semiconductor film. Therefore, there is also a problem in that the activation ratio of the impurity is lowered. As a result, the characteristics and the manufacturing efficiency of the TFT are drastically limited by the above problems.

The present invention is made in consideration of the above problems, and it is an object of the present invention to provide an electro-optical device and a method of manufacturing the same, which, in a TFT for driving a display element in an active manner, can control the limited characteristics and the manufacturing efficiency of the TFT in a desired range and can realize a display with high definition and high brightness, comparable to a silver halide photograph. Further, it is another object of the present invention to provide an electronic apparatus having such an electro-optical device.

In order to solve the above problems, there is provided a method of manufacturing an electro-optical device of the present invention. The method of manufacturing an electro-optical device comprises a step of forming a semiconductor film of a thin film transistor on a base, a step of forming a dummy film to cover the surface of the semiconductor film, a first injection step of injecting a first injection amount of an impurity into the semiconductor film via the dummy film to form a lightly doped region adjacent to a channel region of the thin film transistor, a second injection step of injecting a second injection amount, more than the first injection amount, of an impurity into the semiconductor film via the dummy film to form a source region and a drain region of the thin film transistor adjacent to the lightly doped region, a step of removing the dummy film to expose at least a portion of the channel region, the lightly doped region, the source region, and the drain region, a step of forming a gate insulating film to cover at least the surface of the exposed portion of the semiconductor film, from which the dummy film is removed, and a step of forming a gate electrode of the thin film transistor to overlap at least a portion of the channel region and the lightly doped region on the gate insulating film.

According to the method of manufacturing an electro-optical device of the present invention, an insulating substrate such as a glass substrate is used as the base. In the present invention, however, a substrate on which a base insulating film such as a silicon oxide film is further formed may be used. And then, it is possible to manufacture a TFT having a GOLD structure through manufacturing processes as described below. Further, in the image display region on the base, a TFT is manufactured for every pixel. Thus, it is possible to manufacture an active matrix driving type electro-optical device.

In the method of manufacturing an electro-optical device of the present invention, first, an amorphous silicon film or a polysilicon film is formed on the base including the substrate as the semiconductor film of the TFT. Here, after the semiconductor film is formed on the base, a channel doping may be performed such that an impurity is injected into at least the channel region of the TFT in the semiconductor film with a mask. More specifically, the channel doping is performed on the semiconductor film via other films which are formed on the semiconductor film, and then after the channel doping is completed, the other films are removed.

Next, for example, by means of a plasma CVD (chemical vapor deposition) method, the dummy film is formed to cover the surface of the semiconductor film. The dummy film is formed with, for example, a silicon nitride film or a silicon oxide.

Subsequently, the ion injection is performed on the semiconductor film. More specifically, by performing the first injection step and the second injection step via the dummy film, the ion injection is performed. For example, the first injection step and the second injection step are performed as follows.

In the first injection step, a mask is formed on the dummy film such that the surface of the dummy film overlapping the surface of the channel region of the TFT in the semiconductor film is covered with the mask. And then, the first injection amount of the impurity is injected into the semiconductor film via the dummy film. Accordingly, the lightly doped region is formed adjacent to the channel region of the TFT in the semiconductor film.

Next, in the second injection step, the mask which covers the channel region of the TFT in the semiconductor film in an overlap manner is removed, and an additional mask which covers the surface of the dummy film to overlap the channel region and a portion of the lightly doped region of the TFT in the semiconductor film is formed on the dummy film. And then, the second injection amount of the impurity is injected into the semiconductor film via the dummy film. Accordingly, the source region and the drain region of the TFT are formed adjacent to the lightly doped region.

Moreover, any one of the first and second injection steps may be performed first. For example, the second injection step is performed with the mask which is formed to cover the channel region and the lightly doped region of the TFT in the semiconductor film in an overlap manner. And then, after the mask is retreated from the lightly doped region of the semiconductor film, the first injection step may be performed.

Next, for example, by means of wet etching or dry etching, the dummy film is removed. The dummy film may be removed to expose the semiconductor film or it may be removed to expose at least a portion of the channel region, the lightly doped region, the source region, and the drain region.

Next, the gate insulating film is formed to cover at least the surface of the exposed portion in the semiconductor film from which the dummy film is removed. The gate insulating film is formed with a silicon oxide, for example, by means of a plasma-enhanced CVD method (PE-CVD method) which uses tetra ethyl oxysilane (TEOS) gas as raw gas.

According to the method of manufacturing an electro-optical device of the present invention, after the ion injection is performed on the semiconductor film, the gate insulating film is formed. Thus, it is possible to form the gate insulating film with a desired thickness. In the TFT which is manufactured by the method of manufacturing an electro-optical device of the present invention, the gate insulating film is formed to have such a film thickness in which electrical characteristics as described below are obtained.

Next, the gate electrode is formed on the gate insulating film to overlap a portion of the channel region and the lightly doped region in the semiconductor film. As a result, independently of a planar arrangement of the channel region, the lightly doped region, the source region, and the drain region, that is, in a non-self alignment manner, it is possible to form the TFT. Thus, the TFT having the GOLD structure is formed.

According to the method of manufacturing an electro-optical device of the present invention as described above, the ion injection to the semiconductor film is performed via the dummy film. Thus, the film thickness of the dummy film and the ion injection energy may be suitably set. Therefore, in the lightly doped region, the source region, and the drain region in the semiconductor film, it is possible to prevent the concentration variation of the impurity. That is, it is possible to prevent the concentration of the impurity from increasing at a position deeper than the vicinity of the surface of the semiconductor film.

Further, while the film thickness of the gate insulating film is limited in the self alignment type LDD structure, in the TFT having the GLOD structure, it is possible to form the gate insulating film having the film thickness which is fitted to the electrical characteristics of the TFT. That is, according to the method of manufacturing an electro-optical device of the present invention, the film thickness of the gate insulating film may be adjusted. Thus, it is possible to change the electrical characteristics of the TFT and improve the manufacturing efficiency of the TFT. Therefore, it is possible to reduce an OFF current.

Here, in an active matrix driving type liquid crystal device as the electro-optical device, image signals to be supplied from driving circuit for driving pixels are written into liquid crystal elements and storage capacitors, which are provided with respect to the liquid crystal elements, via a TFT which is turned on by scanning signals to be supplied from the driving circuit. And then, voltages according to the image signals are held in the liquid crystal elements and the storage capacitors.

If such a liquid crystal device is implemented with high definition, the liquid crystal elements and the storage capacitors are miniaturized. Even though the liquid crystal elements and the storage capacitors are miniaturized in such a manner, in the TFT manufactured by the method of manufacturing an electro-optical device of the present invention, it is possible to surely suppress the OFF current. Further, it is possible to perform an image display with high brightness in the respective pixels. Therefore, by using such a liquid crystal device, it is possible to realize a display with high definition and high brightness.

Moreover, the gate insulating film is formed with the thick film. Thus, when the ON current in the TFT is lowered, by adjusting the voltage of the scanning signal for turning on the TFT, the ON current may be adjusted.

In an aspect of the method of manufacturing an electro-optical device of the present invention, in the step of forming the semiconductor film, a low-temperature polysilicon film is formed as the semiconductor film.

According to this aspect, it is possible to manufacture the TFT for every pixel. At the same time, by manufacturing circuit elements, which constitutes the driving circuit, in a peripheral region around the image display region on the base, it is possible to form the driving circuit for driving the display elements or the TFTs. Thus, it is possible to form the driving circuit to be built in the electro-optical device. For this reason, the driving circuit may be formed with an IC or an LSI. As a result, there is no need for an advanced installing technique, as compared to a case in which the driving circuit is installed on the electro-optical device as an external circuit.

In addition, according to such a low-temperature polysilicon technique, it is possible to fabricate the TFT for every pixel on the base having a relatively large size. Thus, according to this aspect, it is possible to easily manufacture the electro-optical device which is used for a relatively large display.

In the aspect in which the low-temperature polysilicon film is formed as the semiconductor film, the method of manufacturing an electro-optical device of the present invention may further comprise a step of patterning the semiconductor film to form a precursor film of a lower capacitor electrode of a storage capacitor, a step of forming a first dielectric film of the storage capacitor on the lower capacitor electrode with the same material as that of the gate insulating film, and a step of forming an upper capacitor electrode of the storage capacitor on the first dielectric film with the same material as that of the gate electrode. Further, the second injection step may be further performed on the precursor film.

If so, it is possible to form the storage capacitor as the driving element for driving the display element in an active matrix manner for every pixel, together with the TFT.

More specifically, in the second injection step, the impurity is injected into the semiconductor film of the TFT via the dummy film, and simultaneously the impurity is injected into the precursor film of the lower capacitor electrode of the storage capacitor which is formed by patterning the semiconductor film, thereby forming the lower capacitor electrode. Further, simultaneously with the step of forming the gate insulating film of the TFT, the first dielectric film of the storage capacitor is formed on the lower capacitor electrode with the same material as that of the gate insulating film. In addition, simultaneously with the step of forming the gate electrode of the TFT, the upper capacitor electrode of the storage capacitor is formed on the first dielectric film with the same material as that of the gate electrode.

In the aspect which further comprises the step of forming the storage capacitor, the method of manufacturing an electro-optical device of the present invention may further comprise a step of forming a second dielectric film of the storage capacitor on the precursor film with the same material as that of the dummy film, and a step of forming a stack electrode of the storage capacitor on the second dielectric film. Further, the second injection step may be further performed on the precursor film via the second dielectric film, and in the step of the forming the first dielectric film, the first dielectric film may be formed on the stack electrode.

If so, it is possible to form a stacked type storage capacitor, together with the TFT. More specifically, simultaneously with the step of forming the dummy film, the second dielectric film is formed on the precursor film of the lower capacitor electrode with the same material as that of the dummy film. And then, in the second injection step, the impurity is injected into the precursor film of the lower capacitor electrode via the second dielectric film, thereby forming the lower capacitor electrode. And then, the first dielectric film is formed on the stack electrode which is formed on the second dielectric film.

Here, as the electro-optical device is implemented with high definition, the display elements and the driving element such as the storage capacitor are miniaturized. By using the storage capacitor of the stacked structure, even though the storage capacitor is miniaturized, it is possible to increase an electrical capacitance. As a result, it is possible to perform an image display with high brightness in each pixel.

In another aspect of the method of manufacturing an electro-optical device of the present invention, in the step of forming the dummy film, the dummy film is formed to have the same etching rate as that of the base.

According to this aspect, it is possible to form the dummy film on a film included in the base, for example, the base insulating film which is formed on the substrate, with the same material as that of the base insulating film. In this case, in the step of removing the dummy film, the dummy film is preferably removed to expose a portion of the channel region, the lightly doped region, the source region, and the drain region in the surface of the semiconductor film, such that the dummy film is remained on the surface of the semiconductor film. Moreover, the etching rate of the dummy may be controlled by selecting the material constituting the dummy film. Alternatively, the etching rate of the dummy film may be controlled by controlling the forming conditions of the dummy film.

In another aspect of the method of manufacturing an electro-optical device of the present invention, in the step of forming the dummy film, the dummy film is formed to have an etching rate different from the base.

According to this aspect, it is possible to take an etching selection ratio of the dummy film and the base. Thus, in the step of removing the dummy film, it becomes easy to remove the dummy film such that the semiconductor film is exposed from the dummy film.

In this aspect in which the dummy film is formed to have the etching rate different from the base, the dummy film may be formed to have an etching rate larger than that of the base.

If so, in the case in which the dummy film is removed such that the semiconductor film is exposed from the dummy film, it is possible to prevent the base from being removed due to overetching.

In this aspect in which the dummy film is formed to have the etching rate larger than that of the base, the dummy film may be formed with a silicon nitride film.

If so, in the case in which the dummy film is formed on the base which has the substrate and the silicon oxide film being formed on the substrate and serving as the base insulating film, it is possible to take an etching selection ratio of the dummy film and the silicon oxide film to be included in the base. For example, in the case in which fluoric acid is used as an etchant and the dummy film is removed by means of wet etching, it is possible to make the etching rate of the silicon nitride oxide four times or more than that of the silicon oxide film. Further, if the storage capacitor of the stacked structure is formed to have a nitride film as the second dielectric film, it is possible to further increase the electrical capacitance.

In the aspect in which the dummy film is formed to have the etching rate equal to or different from the base, the dummy film may be formed with the same material as that of a film which is included in the base.

If so, even though the dummy film is formed with the same material as that of the substrate serving as the base or the base insulating film which is formed on the substrate, by controlling the forming conditions or the like of the dummy film, it is possible to form the dummy film to have the etching rate equal to or different from the base.

In another aspect of the method of manufacturing an electro-optical device of the present invention, the first injection step and the second injection step are performed with an n-type impurity.

If so, in the first injection step and the second injection step, the n-type impurity, for example, phosphorus (P) is injected into the semiconductor film via the dummy film, such that it is possible to form an N-channel type TFT.

In another aspect of the method of manufacturing an electro-optical device of the present invention, the first injection step and the second injection step are performed with a p-type impurity.

If so, in the first injection step and the second injection step, the p-type impurity, for example, boron (B) is injected into the semiconductor film via the dummy film, such that it is possible to form a P-channel type TFT. Further, if the P-channel type TFT is formed, it is possible to further reduce the OFF current in the TFT, as compared to the case in which the N-channel type TFT is formed.

In order to solve the above problems, there is provided an electro-optical device of the present invention which is manufactured by a method of manufacturing an electro-optical device as described above (various aspects described above are also included). The electro-optical device comprises display elements which are arranged in a predetermined pattern in an image display region on a base and which are respectively driven in an active manner by means of thin film transistors.

According to the electro-optical device of the present invention, at the time of the operation, the display elements such as the liquid crystal elements are driven by means of the TFTs in an active manner, such that it is possible to perform the image display. At this time, the TFT is a non-self alignment type and has excellent transistor characteristics such as the OFF current characteristics. Thus, according to the electro-optical device of the present invention, it is possible to realize the display with high definition and high brightness.

In order to solve the above problems, there is provided an electronic apparatus of the present invention having an electro-optical device as described above.

The electronic apparatus of the present invention has the electro-optical device of the present invention described above. Thus, various electronic apparatus which can perform the image display with high definition and high brightness, such as a projection display device, a television, a cellular phone, an electronic organizer, a word processor, a view finder type or monitor-direct-view type video tape recorder, a workstation, a videophone, a POS terminal, a touch panel or the like, can be realized. Further, as the electronic apparatus of the present invention, for example, an electrophoresis device, such as an electronic paper, an electron emission device (field emission display and conduction electron-emitter display) or a DLP (digital light processing) using the electrophoresis device or the electron emission device can be realized.

The operations and advantages of the present invention will be apparent from embodiments described below.

### BRIEF DESCRIPTION OF THE DRAWINGS

FIG. 1 is a plan view showing an entire configuration of an electro-optical device;

FIG. 2 is a cross-sectional view taken along a line H-H′ of FIG. 1;

FIG. 3 is an equivalent circuit diagram of various elements, wiring lines or the like in a plurality of pixels which is formed in a matrix type and constitutes an image display region of the electro-optical device;

FIG. 4 is a plan view of an arbitrary pixel portion on a TFT array substrate on which data lines, scanning lines, pixel electrodes or the like are formed;

FIG. 5 is a cross-sectional view taken along a line A-A′ of FIG. 4;

FIGS. 6A-6C are diagrams showing a cross-sectional configuration of the TFT array substrate sequentially in relation to steps of a manufacturing process (first process);

FIGS. 7A-7C are diagrams showing a cross-sectional configuration of the TFT array substrate sequentially in relation to steps of a manufacturing process (second process);

FIGS. 8A-8C are diagrams showing a cross-sectional configuration of the TFT array substrate sequentially in relation to steps of a manufacturing process (third process);

FIGS. 9A and 9B are diagrams showing a cross-sectional configuration of the TFT array substrate sequentially in relation to steps of a manufacturing process (fourth process);

FIG. 10 is a graph showing electrical characteristics of a TFT;

FIG. 11 is a plan view of an arbitrary pixel portion on a TFT array substrate, on which data lines, scanning lines, pixel electrodes or the like are formed, according to a second embodiment;

FIG. 12 is a cross-sectional view taken along a line B-B′ of FIG. 11;

FIGS. 13A-13D are diagrams showing a cross-sectional configuration of the TFT array substrate sequentially in relation to steps of a manufacturing process according to the second embodiment (first process);

FIGS. 14A-14D are diagrams showing a cross-sectional configuration of the TFT array substrate sequentially in relation to steps of a manufacturing process according to the second embodiment (second process);

FIG. 15 is a diagram showing a cross-sectional configuration of the TFT array substrate sequentially in relation to steps of a manufacturing process according to the second embodiment (third process);

FIGS. 16A and 16B are cross-sectional views showing a cross-sectional configuration of a TFT array substrate in relation to a step of removing a dummy film according to a modification of the second embodiment;

FIG. 17 is a plan view showing a configuration of a projector as an example of an electronic apparatus to which a liquid crystal device is applied;

FIG. 18 is a perspective view showing a configuration of a personal computer as an example of an electronic apparatus to which a liquid crystal device is applied; and

FIG. 19 is a perspective view showing a configuration of a cellular phone as an example of an electronic apparatus to which a liquid crystal device is applied.

### DETAILED DESCRIPTION OF EMBODIMENTS

Embodiments of the present invention will be now described with reference to the drawings. In the embodiments, an electro-optical device of the present invention is applied to a liquid crystal device.

### 1: First Embodiment

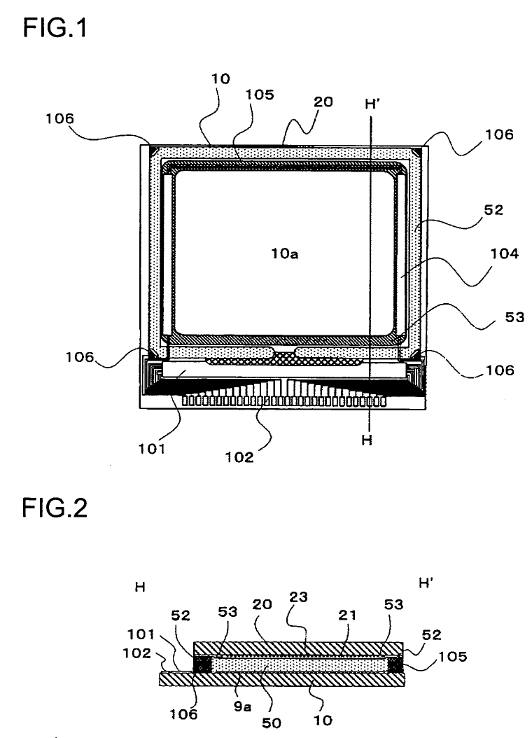

To begin with, a first embodiment of an electro-optical device according to the present invention will be described with reference to FIGS. 1 to 10.

<1-1: Entire Configuration of Electro-Optical Device>

First, an entire construction of the electro-optical device of the present invention will be described with reference to FIGS. 1 and 2. FIG. 1 is a plan view of the electro-optical device showing a TFT array substrate and elements formed thereon, as seen from a counter substrate, and FIG. 2 is a cross-sectional view taken along a line H-H′ of FIG. 1. Herein, a TFT active matrix driving type liquid crystal device in which driving circuits are built is used as an example of the electro-optical device.

Referring to FIGS. 1 and 2, in the electro-optical device according to the present embodiment, a TFT array substrate 10 and a counter substrate 20 are arranged to oppose each other. Between the TFT array substrate 10 and the counter substrate 20, a liquid crystal layer 50 is sealed. The TFT array substrate 10 and the counter substrate 20 are bonded to each other by means of a sealing material 52 which is provided at a sealing region around an image display region 10a.

The sealing material 52 for bonding the TFT array substrate 10 and the counter substrate 20 is made of, for example, ultraviolet curable resin or thermosetting resin. In a manufacturing process, the sealing material 52 is applied on the TFT array substrate 10, and then cured by means of ultraviolet irradiation or heating. Further, in the sealing material 52, to maintain a gap between the TFT array substrate 10 and the counter substrate 20 with a predetermined value, gap materials such as glass fibers or glass beads are distributed.

Parallel with an inner side of the sealing region at which the sealing material 52 is disposed, a frame light-shielding film 53 defining a frame region of the image display region 10a is provided on the counter substrate 20. However, a portion or an entire portion of the frame light-shielding film 53 may be embedded in the TFT array substrate 10.

In a peripheral region around the image display region 10a, a data line driving circuit 101 and external circuit connecting terminals 102 are provided in a region outside the sealing region on which the sealing material 52 is arranged along a side of the TFT array substrate 10. Further, scanning line driving circuits 104 are provided along two sides adjacent to the side such that the scanning line driving circuits 104 are covered with the frame light-shielding film 53. In addition, to connect the two scanning line driving circuits 104 disposed at both sides of the image display region 10a, a plurality of wiring lines 105 are provided along a remaining side of the TFT array substrate 10 such that a plurality of the wiring lines are covered with the frame light-shielding film 53.

In four corners of the counter substrate 20, vertically conducting members 106, each functioning as a vertically conducting terminal between both substrates, are disposed. Further, in regions of the TFT array substrate 10 opposing the corners, vertically conducting terminals are provided. In such a construction, it is possible to electrically connect the TFT array substrate 10 to the counter substrate 20.

In FIG. 2, after TFTs for switching pixels or wiring lines such as scanning lines and data lines are formed on the TFT array substrate 10, an alignment film is formed on pixel electrodes 9a. Meanwhile, on the counter substrate 20, counter electrodes 21, a light shielding film 23 in a lattice or stripe shape, an alignment film formed on an uppermost or the like are formed. Further, the liquid crystal layer 50 is made of, for example, one or more nematic liquid crystal materials, and is aligned in a predetermined direction between a pair of the alignment films.

Moreover, on the TFT array substrate 10 shown in FIGS. 1 and 2, in addition to the data line driving circuit 101 and the scanning line driving circuits 104, a sampling circuit for sampling image signals on image signal lines and supplying the sampled image signals to the data lines, a precharge circuit for supplying a precharge signal having a predetermined voltage level to the data lines prior to the sampled image signals, a test circuit for testing a quality and defect of the electro-optical device during the manufacturing process or at the time of shipment may be formed.

<1-2: Construction in Pixel Portion>

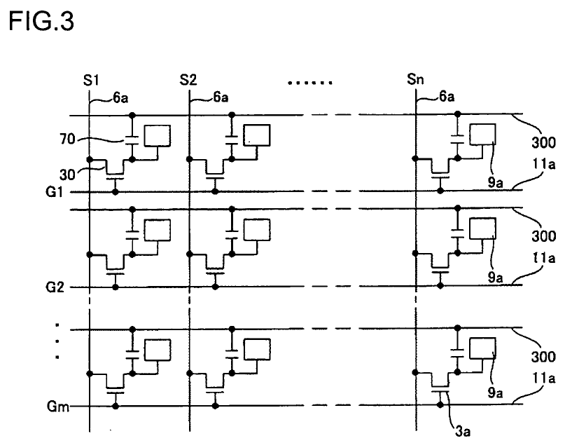

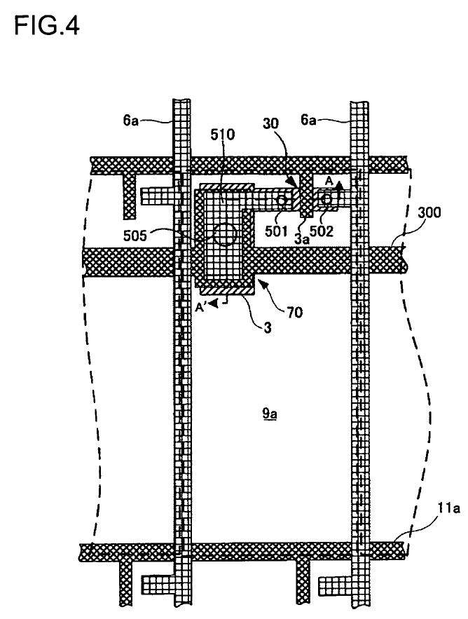

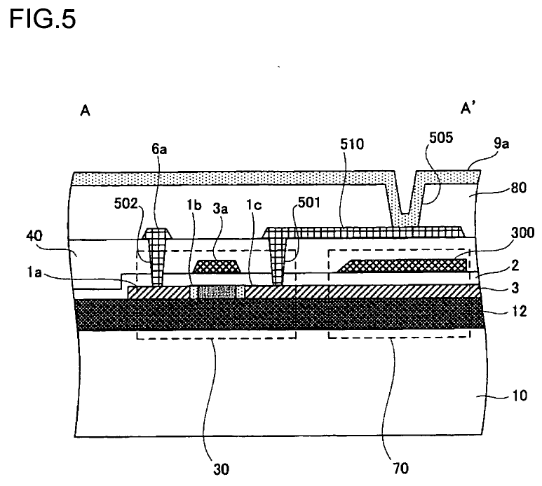

A construction in a pixel portion of the electro-optical device in the embodiment of the present invention will be now described with reference to FIGS. 3 to 5. FIG. 3 is an equivalent circuit diagram of various elements, wiring lines or the like in a plurality of pixels which is formed in a matrix type and constitutes an image display region of the electro-optical device, and FIG. 4 is a plan view of an arbitrary pixel portion on a TFT array substrate on which data lines, scanning lines, pixel electrodes or the like are formed. In addition, FIG. 5 is a cross-sectional view taken along a line A-A′ of FIG. 4. Moreover, in FIG. 5, to make each layer and each member to be sufficiently understandable size, each layer and each member is shown with a different scale.

In FIG. 3, in each of a plurality of pixels which is arranged in a matrix type and constitutes the image display region of the electro-optical device according to the present embodiment, a pixel electrode 9a and a TFT 30 for switching the pixel electrode 9a are formed, and a source of the TFT 30 is electrically connected to the data line 6a to which the image signal is supplied. The image signals S1, S2, . . . , Sn to be written in the data lines 6a may be line-sequentially supplied to the data lines 6a in this order or may be supplied in a group to a plurality of adjacent data lines 6a.

Further, a gate of the TFT 30 is electrically connected to a gate electrode 3a, and thus scanning signals G1, G2, . . . , Gm are line-sequentially applied to the scanning lines 11a and the gate electrodes 3a at a predetermined time interval as a pulse. The pixel electrode 9a is electrically connected to a drain of the TFT 30, and by turning on the TFT 30 serving as a switching element for a predetermined period, the image signals S1, S2, . . . , Sn supplied from the data lines 6a are written in the pixel electrodes 9a at a predetermined time interval.

The image signals S1, S2, . . . , Sn of a predetermined level written in liquid crystal as an electro-optical material via the pixel electrodes 9a are hold between the pixel electrode 9a and the counter electrode 21 formed on the counter substrate 20 for a predetermined period. An alignment or order of liquid crystal molecules changes according to an applied voltage level, and light is modulated, whereby it is possible to display gray scales. In a normally white mode, for each pixel, transmittance with respect to incident light decreases according to the applied voltage. In a normally black mode, for each pixel, transmittance with respect to incident light increases according to the applied voltage. As a whole, contrast of light emitted from the electro-optical device corresponds to the image signal.

Here, in order to prevent the held image signal from leaking, storage capacitors 70 are added parallel to liquid crystal capacitors which are formed between the pixel electrodes 9a and the counter electrodes 21. The storage capacitors 70 are provided parallel to the scanning lines 11a, each having a fixed potential capacitor electrode and a capacitor electrode 300 which is fixed to a constant potential.

Hereinafter, a construction on the TFT array substrate 10 in one pixel will be described in detail with reference to FIGS. 4 and 5.

In FIG. 5, the TFT array substrate 10 is made of an insulating transparent substrate such as a glass substrate. On the TFT array substrate 10, for example, a silicon oxide film (SiO₂) is formed as a base insulating film 12. The film thickness of the base insulating film 12 is preferably set in a range of from 300 [nm] to 800 [nm]. And then, in the present invention, ‘the base’ includes the TFT array substrate 10 and the base insulating film 12.

On the base insulating film 12, the N-channel type TFT 30 and the storage capacitor 70 are formed. In FIGS. 4 and 5, the TFT 30 comprises a semiconductor film 3, a gate insulating film 2 and a gate electrode 3a. The semiconductor film 3 is formed on the base insulating film 12, for example, at a film thickness in a range of from 30 [nm] to 70 [nm]. Further, semiconductor film 3 is formed with a film (hereinafter, referred to as a low-temperature polysilicon film) which is formed by poly-crystallization from an amorphous silicon film by means of a laser annealing method. In the semiconductor film 3, lightly doped regions 1b into which an n-type impurity is injected are formed with a channel region of the TFT 30 interposed therebetween. Further, in the semiconductor film 3, adjacent to the lightly doped regions 1b, a source region 1a and a drain region 1c into which the n-type impurity is more heavily doped than those of the lightly doped regions 1b are formed.

Further, on the semiconductor film 3, the gate insulating film 2 made of, for example, a silicon oxide film (SiO₂) is formed to cover the semiconductor film 3. In the present embodiment, in the TFT 30, the gate insulating film 2 is formed to have a film thickness such that electrical characteristics as described below are obtained. The film thickness of the gate insulating film 2 is preferably 100 [nm] or more.

In addition, in a region on the gate insulating film 2 overlapping the channel region and portions of the lightly doped regions 1b of the TFT 30 in the semiconductor film 3, the gate electrode 3a is formed. That is, the TFT 30 shown in FIGS. 4 and 5 has a GOLD structure.

Here, the gate electrode 3a is made of a multilayer of titanium (Ti) and an alloy of aluminum (Al) and copper (Cu), a laminate of aluminum (Al) and molybdenum (Mo), or chromium (Cr). Further, the film thickness of the gate electrode 3a is set to, for example, 400 [nm], and an overlapping length of the gate electrode 3a and the lightly doped region 1b is preferably in a range of from 0.25 [μm] to 0.75 [μm] in consideration of alignment deviation of the gate electrode 3a and the semiconductor film 3. In addition, the length of the lightly doped region 1b in the semiconductor film 3 in a channel direction is preferably adjusted to have a value such that end portions of the gate electrode 3a overlap the lightly doped regions 1b, even when an alignment deviation is generated.

Further, in FIGS. 4 and 5, the storage capacitor 70 is formed by means of a lower capacitor electrode formed by a portion of the semiconductor film 3 and the capacitor electrode 300 serving as a fixed potential capacitor electrode, which are arranged to oppose each other with a portion of the gate insulating film 2 interposed therebetween. More specifically, a portion of the region in the semiconductor film 3, in which the n-type impurity is doped more highly than those of the lightly doped regions 1b, is formed as the lower capacitor electrode. That is, the lower capacitor electrode and a drain region 1c of the TFT 30 are connected to each other. Further, ‘the first dielectric film’ is formed with a portion of the gate insulating film 2 interposed between the lower capacitor electrode and the capacitor electrode 300. Moreover, the capacitor electrode 300 and the scanning line 11a are preferably formed with the same conductive film as that of the gate electrode 3a.

Referring to FIG. 5, a first interlayer insulating film 40 is formed to cover the gate electrode 3a, the capacitor electrode 300, and the scanning line 11a which is not shown in FIG. 5. In the first interlayer insulating film 40, contact holes 501 and 502 which pass through the first interlayer insulating film 40 and the gate insulating film 2 and extend from the surface of the first interlayer insulating film 40 to surfaces of the drain region 1c and the source region 1a in the semiconductor film 3 are formed. And then, the contact holes 501 and 502 are filled with a conductive material, such that the data line 6a which is electrically connected to a source of the TFT 30 and a drain electrode 510 are formed on the first interlayer insulating film 40.

Further, on the first interlayer insulating film 40, a second interlayer insulating film 80 is formed. And then, a contact hole 505 which passes through the second interlayer insulating film 80 and extends from the surface of the second interlayer insulating film 80 to the surface of the drain electrode 510 is opened. The contact hole 505 is filled with a conductive material made of, for example, ITO (indium tin oxide), such that the pixel electrode 9a is formed in a region corresponding to an opened region of the pixel portion as shown in FIG. 4.

<1-2: Manufacturing Method of Electro-Optical Device>

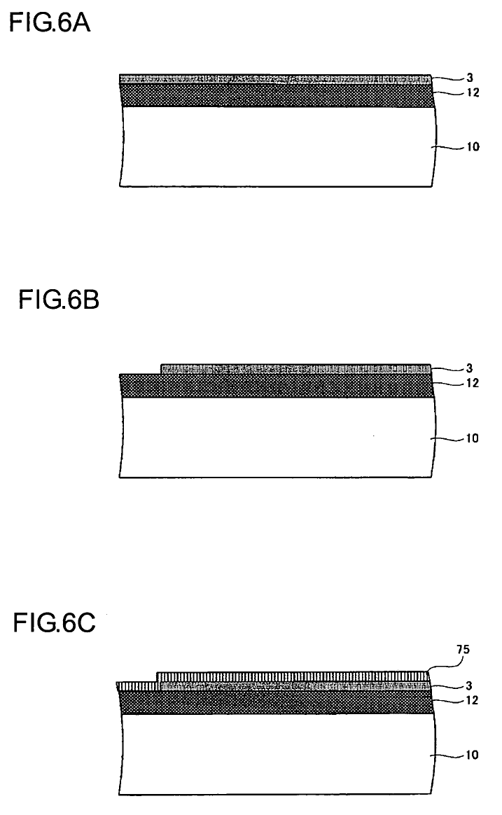

A method of manufacturing the electro-optical device described above will now be described with reference to FIGS. 6 to 9. Hereinafter, a manufacturing process relating to elements on the TFT array substrate 10 shown in FIGS. 4 and 5 will be specifically described in detail, and descriptions of a manufacturing process relating to other elements shown in FIGS. 1 and 2 will be omitted.

Here, FIGS. 6 to 9 are diagrams showing a cross-sectional configuration of the TFT array substrate 10 shown in FIG. 5 sequentially in relation to steps of a manufacturing process.

First, in FIG. 6(a), on the base insulating film 12 formed on the TFT array substrate 10, the semiconductor film 3 which is formed by poly-crystallizing the amorphous silicon film by means of the laser annealing method is formed. Here, after the semiconductor film 3 is formed, by injecting the impurity into the channel region of the TFT 30, a channel doping may be performed. Such a channel doping is performed by injecting the impurity into the semiconductor film 3 with an injection amount of 5×10¹² [ions/cm²] or less via a mask and other films formed on the semiconductor film 3. And then, after the channel doping is completed, other films and the mask are removed from the semiconductor film 3.

Next, in FIG. 6(b), patterning is performed on the semiconductor film 3, such that the semiconductor film 3 is formed as a film having a pattern in a plan view as shown in FIG. 4. Accordingly, a portion of the semiconductor film 3 which constitutes a precursor film of the lower capacitor electrode of the storage capacitor is formed.

Subsequently, in FIG. 6(c), a dummy film 75 is formed to cover the semiconductor film 3, for example, by means of a plasma CVD method. The dummy film 75 is formed with, for example, a silicon nitride and, for example, to have a film thickness of 30 [nm]. Moreover, the dummy film 75 may be formed to cover the surface of the base insulating film 12 or may be formed to cover at least the surface of the semiconductor film 3. The film thickness of the dummy film 75 is set to a value of the accelation energy which can optimize the injection of the impurity. It should be determined in consideration of the increase in the temperature of the substrate or the activation ratio of the impurity at its temperature.

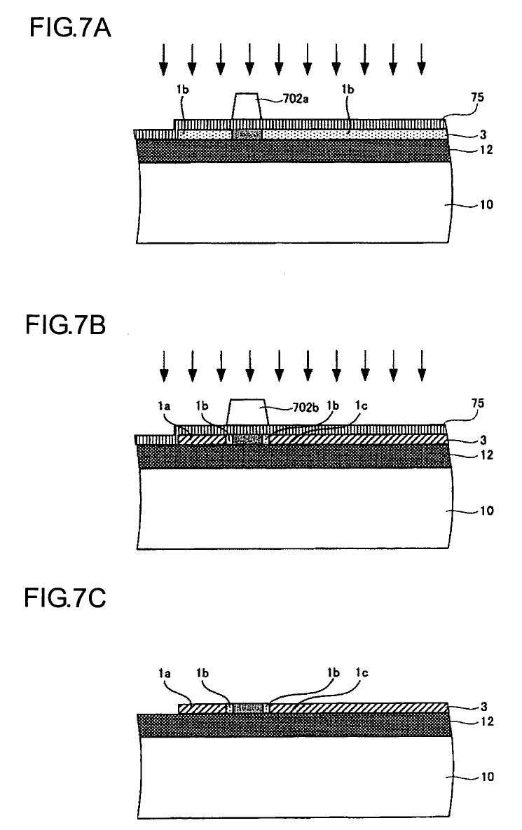

Subsequently, an ion injection is performed on the semiconductor film 3 by means of the following first injection step and second injection step. First, in the first injection step, as shown in FIG. 7(a), a resist pattern is formed on the dummy film 75 as a mask 702a, for example, by means of a photolithography method, such that the mask 702a covers the surface of the dummy film 75 which overlaps the surface of the channel region of the TFT 30 in the semiconductor film 3. And then, phosphorus (P) as the n-type impurity is injected into the semiconductor film 3 with a first injection amount ranging from 1×10¹³ [ions/cm²] to 8×10¹³ [ions/cm²] via the dummy film 75 with the mask 702. Accordingly, the lightly doped regions 1b of the TFT 30 are formed in the semiconductor film 3.

Next, in the second injection step, as shown in FIG. 7(b), the mask 702a is removed, and then an additional mask 702b is formed on the dummy film 75 to overlap the surfaces of portions of the channel region and the lightly doped regions 1b of the TFT 30 in the semiconductor film 3. And then, phosphorus (P) as the n-type impurity is injected into the semiconductor film 3 with a second injection amount ranging from 1×10¹⁵ [ions/cm²] to 1×10¹⁶ [ions/cm²] via the dummy film 75 with the mask 702b. Accordingly, the source region 1a and the drain region 1c of the TFT 30 are formed adjacent to the lightly doped regions 1b in the semiconductor film 3. In addition, the second injection amount of the n-type impurity is injected into a portion of the semiconductor film 3 which constitutes the precursor film of the lower capacitor electrode of the storage capacitor 70, such that the lower capacitor electrode is formed.

After the mask 702b is removed, as shown in FIG. 7(c), the dummy film 75 is removed, for example, by means of a wet etching method. Here, when the dummy film 75 is formed with the silicon nitride film, wet etching is performed using fluoric acid or BHF (buffered hydrofluoric acid) as an etchant, such that it is possible to easily make an etching rate of the dummy film 75 four times or more faster or larger than that of the silicon oxide film serving as the base insulating film 12. Therefore, it is possible to remove completely the dummy film 75 while preventing the base insulating film 12 from being removed due to overetching, such that the semiconductor film 3 is exposed. Moreover, the removal of the dummy film 75 can be performed by means of dry etching in which a mixed gas made mainly of CF₄ is used. Similarly, in case of dry etching, the etching rate of the dummy film 75 is also set to be larger than that of the silicon oxide film.

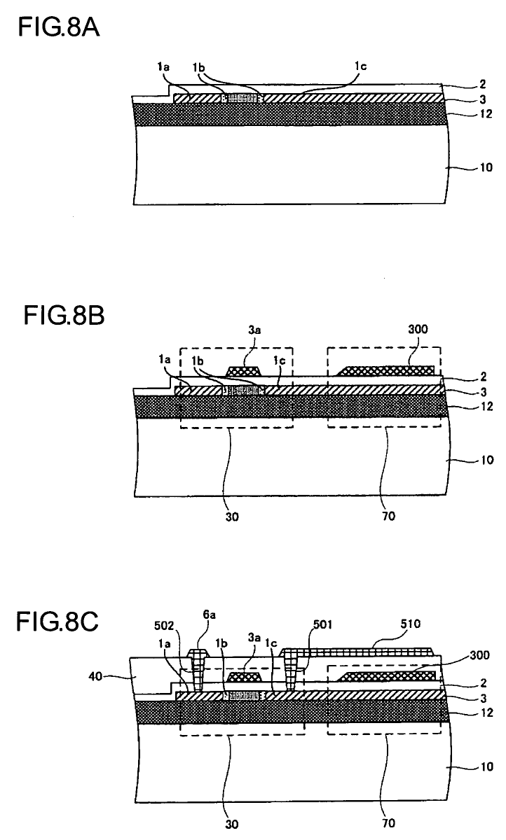

Subsequently, in FIG. 8(a), the gate insulating film 2 of the silicon oxide film is formed by means of a PE-CVD method in which, for example, a TEOS gas is used as a source gas. Here, the film thickness of the gate insulating film 2 is determined in consideration of desired transistor characteristics described below. For example, the film thickness of the gate insulating film 2 is set to 200 nm. Before and after the formation of the gate insulating film 2, annealing or hydrogenation is suitably performed, and then the injected impurity is activated. Subsequently, in FIG. 8(b), the gate electrode 3a, the capacitor electrode 300, and the scanning line 11a which is not shown in FIG. 8(b) are formed. As a result, it is possible to form the TFT 30, independently of a planar arrangement of the channel region, the lightly doped regions 1b, the source region 1a, and the drain region 1c, that is, in a non-self alignment manner. Further, together with the TFT 30, the storage capacitor 70 is also formed.

Next, in FIG. 8(c), the first interlayer insulating film 40 is formed, and the contact holes 501 and 502 are opened. And then, the contact holes 501 and 502 are filled with the conductive material, thereby forming the data line 6a and the drain electrode 510.

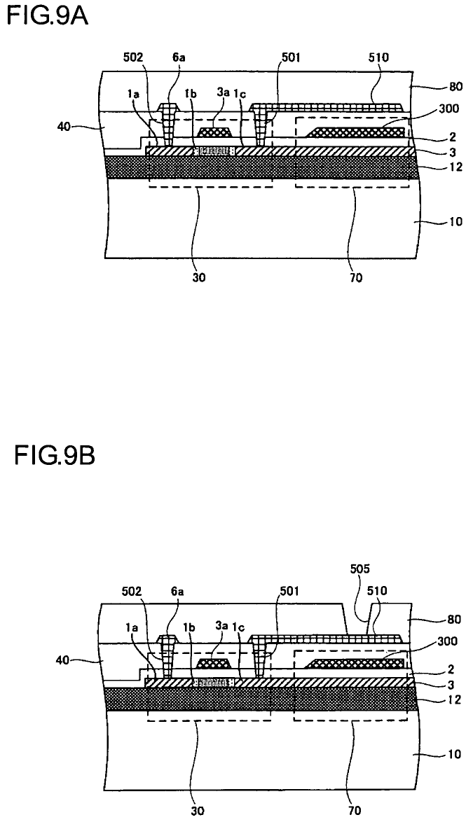

Next, in FIG. 9(a), the smoothed second interlayer insulating film 80 is formed, and then, in FIG. 9(b), the contact hole 505 is opened in the second interlayer insulating film 80. Subsequently, the contact hole 505 is filled with the transparent conductive material, thereby forming the pixel electrode 9a.

According to the method of manufacturing an electro-optical device of the present embodiment, the ion injection to the semiconductor film 3 is performed via the dummy film 75. And then, the density of the impurity in a film-thicknesswise direction of the dummy film 75 and the semiconductor film 3 by means of the ion injection has a distribution according to the injection energy. That is, at a depth which is determined according to an ability of decelerating ions in the dummy film 75 and the semiconductor film 3 (an ability of absorbing the energy) and the ion injection energy, the density of the impurity has a peak value. Therefore, by suitably setting the film thickness of the dummy film and the ion injection energy, in the lightly doped regions 1b, the source region 1a, and the drain region 1c of the semiconductor film 3, it is possible to prevent the concentration variation of the impurity of which the concentration becomes large at a position deeper than the vicinity of the surface. That is, it is possible to fit the peak value of the impurity concentration to the height of the semiconductor film 3 on the substrate 10.

In addition, in the case in which the impurity is injected into the semiconductor film 3 via the gate insulating film 2, if the film is thick and the injection energy is high, there is an adverse effect due to the substrate heating. Further, if the film is thin and the injection energy is low, the temperature of the substrate does not rise, and thus the impurity does not react to the silicon semiconductor film. Therefore, there is also a problem in that the activation ratio of the impurity is lowered. As a result, characteristics and manufacturing efficiency of the TFT are drastically limited by the above-mentioned problems.

Here, in the method of manufacturing an electro-optical device of the present embodiment, after the ion injection is performed on the semiconductor film 3, the gate insulating film 2 is formed. For this reason, it is possible to form the film thickness of the gate insulating film 2 which is fitted to the electrical characteristics of the TFT 30. As described above, in the self alignment type LDD structure, the film thickness of the gate insulating film 2 is limited. Thus, it is possible to improve the manufacturing efficiency of the TFT 30.

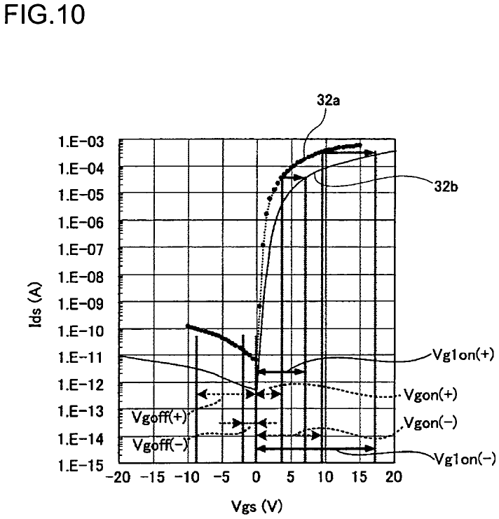

FIG. 10 shows the electrical characteristics of the TFT 30 which is manufactured by the method of manufacturing an electro-optical device of the present embodiment. In FIG. 10, a vertical axis represents a drain current [A] and a horizontal axis represents a gate voltage [V]. Referring to an electrical characteristic curve 32b of the TFT 30 of a GOLD structure having a thick gate insulating film, a so-called jump-up current at the time of turning on is suppressed and an OFF current is reduced, as compared to an electrical characteristic curve 32a of the TFT of the self alignment LDD structure having a thin gate insulating film of 40 percent of the film thickness of the gate insulating film in the GOLD structure. This is because the gate electrode becomes thick in the GOLD structure, such that an electric field which is applied from the gate electrode to a drain junction of the semiconductor film can be lowered. Further, before the gate electrode having a low degree of thermal tolerance is formed, defects in the semiconductor film can be recovered by means of an annealing method or a hydrogen treatment method. That is, according to the method of manufacturing an electro-optical device of the present embodiment, by adjusting the film thickness of the gate insulating film 2, it is possible to change the electrical characteristics of the TFT 30 and reduce the OFF current.

Here, as the electro-optical device is implemented with high definition, the miniaturization of the liquid crystal element and the storage capacitor 70 are demanded. Even though the liquid crystal element and the storage capacitor 70 are miniaturized, the OFF current in the TFT 30 can be suppressed. Thus, it is possible to perform the image display with high brightness in the pixels. Therefore, it is possible to realize the display with high definition and high brightness.

In addition, FIG. 10 shows an ON voltage Vgon and an OFF voltage Vgoff of the TFT when the pixels are driven in alternating current (AC) wise. In a case in which an AC voltage is applied to the liquid crystal layer 50, an operation point changes according to the polarity of the AC voltage, a minimum gate voltage is different. It is assumed that when the pixel electrode 9a has a high potential with respect to the counter substrate 20, the AC voltage has a positive polarity (+), and when the pixel electrode 9a has a low potential with respect to the counter substrate 20, the AC voltage has a negative polarity (−). If so, the ON voltage Vgon(+) at the time of the positive polarity (+) and the ON voltage Vgon(−) at the time of the negative polarity (−) are different from each other. Similarly, the OFF voltage Vgoff(+) at the time of the positive polarity (+) and the OFF voltage Vgoff(−) at the time of the negative polarity (−) are also different from each other.

Here, in the TFT 30 having the GOLD structure, by making the film thickness of the gate insulating film 2 thick, it is possible to reduce the OFF current, but the ON current is also reduced. In this case, by adjusting the voltages of the scanning signals G1, G2, . . . , Gm shown in FIG. 3 respectively, the ON voltage Vg1on(+) at the time of the positive polarity (+) and the ON voltage Vg1on(−) at the time of the negative polarity (−) are adjusted respectively, such that it is possible to increase the ON current. Since the gate insulating film 2 is thick, even though the ON voltage increases, there is no problem in terms of high-voltage resistance.

In addition, by forming the semiconductor film 3 as the low-temperature polysilicon film, it is possible to manufacture the driving elements such as the TFT 30, the storage capacitor 70 and so on for every pixel. At the same time, it is possible to form the data line driving circuit 101 or the scanning line driving circuit 104 in the peripheral region around the image display region 10a on the TFT array substrate 10. Thus, the data line driving circuit 101 or the scanning line driving circuit 104 may be formed with ICs or an LSIs. As a result, there is no need for an advanced installing technique which is required for installing the driving circuit on the electro-optical device as an external circuit. Further, according to such a low-temperature polysilicon technique, it is possible to fabricate the TFT 30 or the like for every pixel on the TFT array substrate 10 having a relatively large size. Thus, it is possible to easily manufacture an electro-optical device which is used for a relatively large display.

Moreover, in the method of manufacturing an electro-optical device of the present embodiment, a sequence of the first and second injection steps is not limited to that described with reference to FIGS. 7(a) and 7(b), but any one of them may be performed first. For example, after the second injection step is performed using a mask which is formed to cover the channel region and the lightly doped regions 1b of the TFT 30 in the semiconductor film 3 in an overlap manner, the mask may be retreated from the lightly doped regions 1b of the semiconductor film 3, and then the first injection step may be performed.

Further, the TFT 30 may be formed as a P-channel type. In the first injection step and the second injection step, by injecting boron (B) as a p-type impurity into the semiconductor film 3 via the dummy film 75, it is possible to form the P-channel type TFT 30. In such a manner, if the P-channel type TFT 30 is formed, it is possible to further reduce the OFF current in the TFT 30, as compared to the case in which the N-channel type TFT 30 is formed.

### 2: Second Embodiment

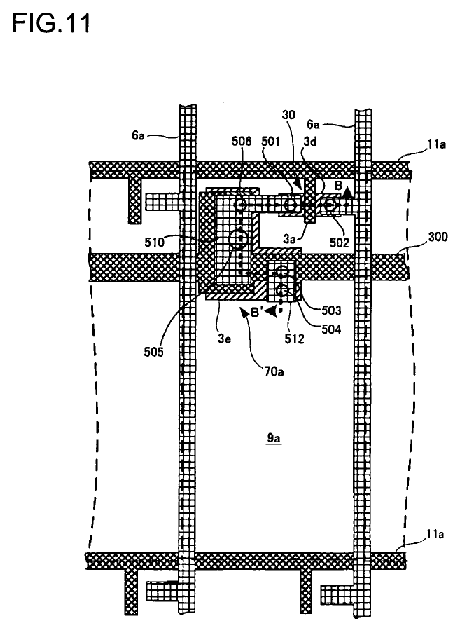

Next, a second embodiment of an electro-optical device according to the present invention will be described. In the second embodiment, a configuration of a storage capacitor in the pixel portion is different from that in the first embodiment. Thus, only different elements from those in the first embodiment will be described in detail with reference to FIGS. 11 to 15.

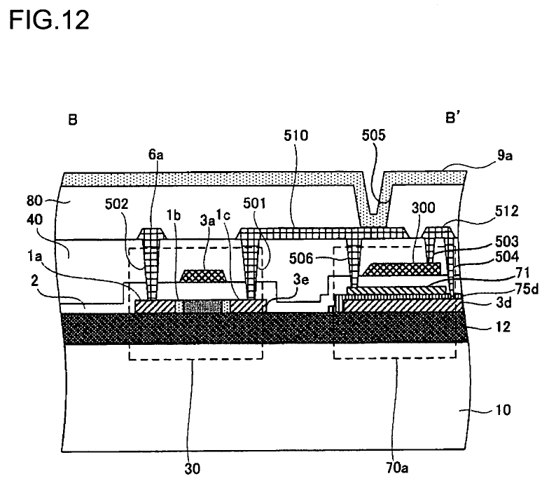

FIG. 11 is a plan view of an arbitrary pixel portion on a TFT array substrate, on which data lines, scanning lines, pixel electrodes or the like are formed, and FIG. 12 is a cross-sectional view taken along a line B-B′ of FIG. 11. Moreover, in FIG. 12, to make each layer and each member to be sufficiently understandable size, each layer and each member is shown with a different scale.

In the second embodiment, the storage capacitor 70 has a stacked configuration. As shown in FIG. 11, a semiconductor film 3d constituting a lower capacitor electrode of a storage capacitor 70a and a semiconductor film 3e of the TFT 30 are formed in a separate pattern from each other on a substrate surface of the TFT array substrate 10 in a plan view. Further, in FIG. 12, between the capacitor electrode 300 and the semiconductor film 3d constituting the lower capacitor electrode, a second dielectric film 75d and a stack electrode 71 are sequentially deposited. Further, between the stack electrode 71 and the capacitor electrode 300, a portion of the gate insulating film 2 constituting the first dielectric film of the storage capacitor 70a is interposed. And then, between the stack electrode 71 and the semiconductor film 3d constituting the lower capacitor electrode, the second dielectric film 75d is interposed. The second dielectric film 75d is formed by leaving a portion of the dummy film in a manufacturing process as described below.

Here, the stack electrode 71 has a film thickness of, for example, 300 [nm] and is made of a non-transmissive material such as chromium (Cr), titanium (Ti), tungsten (W), a laminate of titanium (Ti) and an alloy of aluminum (Al) and copper (Cu), or a laminate of aluminum (Al) and molybdenum (Mo). In the second embodiment, the stack electrode 71 may be made of a pattern which can serve as a light-shielding film defining an opened region in each pixel.

Further, in FIGS. 11 and 12, in the first interlayer insulating film 40, a contact hole 506 which passes through the first interlayer insulating film 40 and the gate insulating film 2 and extends from the surface of the first interlayer insulating film 40 to the surface of the stack electrode 71 is formed. And then, the contact hole 506 is filled with a conductive material which constitutes the drain electrode 510. Further, in the first interlayer insulating film 40, a contact hole 503 which passes through the first interlayer insulating film 40 and extends from the surface of the first interlayer insulating film 40 to the surface of the capacitor electrode 300 is formed. Also, a contact hole 504 which passes through the first interlayer insulating film 40, the gate insulating film 2 and the second dielectric film 75d and extends from the surface of the first interlayer insulating film 40 to the surface of the semiconductor film 3d constituting the lower capacitor electrode is also formed. And then, the contact holes 503 and 504 are filled with a conductive material, such that a connecting electrode 512 for connecting the capacitor electrode 300 and the dielectric film 75d is further formed on the first interlayer insulating film 40.

Thus, according to the second embodiment, even though the electro-optical device is implemented with high definition and the storage capacitor 70a is miniaturized, it is possible to increase the electrical capacitance, as compared to the storage capacitor 70 in the first embodiment. As a result, it is possible to perform the image display with high brightness in each pixel. Further, by constituting the second dielectric film 75d with a silicon oxide film having a high specific dielectric constant, it is possible to further increase the electrical capacitance of the storage capacitor 70a.

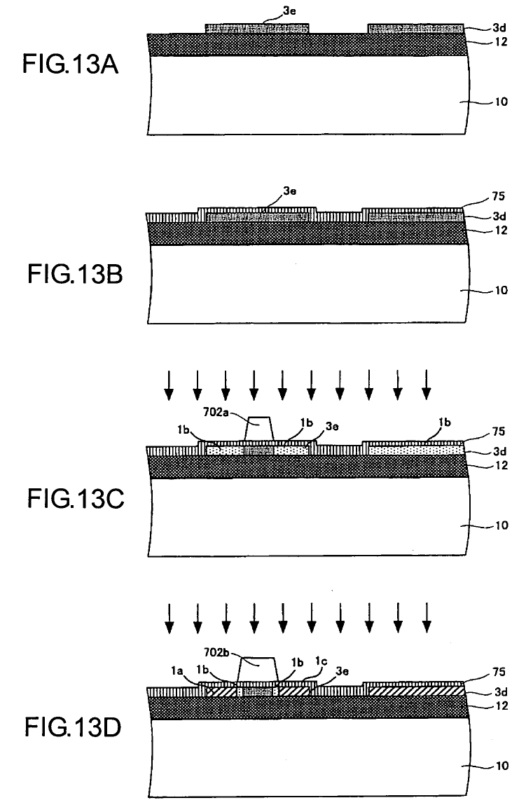

Subsequently, a method of manufacturing the electro-optical device of the second embodiment will be described with reference to FIGS. 13 to 15. Hereinafter, only different elements from those in the first embodiment will be described.

Here, FIGS. 13 to 15 are diagrams showing a cross-sectional configuration of the TFT array substrate 10 shown in FIG. 10 sequentially in relation to steps of a manufacturing process.

First, in FIG. 13(a), the semiconductor film 3d constituting the precursor film of the lower capacitor electrode of the storage capacitor 70a and the semiconductor film 3e of the TFT 30 are respectively formed in a pattern as shown in FIG. 11 in a plan view.

Next, in FIG. 13(b), the dummy film 75 is formed to cover the semiconductor films 3d and 3e, and, as shown in FIGS. 13(c) and 13(d), the ion injections are performed to the semiconductor films 3d and 3e via the dummy film 75 by means of the first and second injection steps. As shown in FIG. 13(c), the lightly doped regions 1b are formed in the semiconductor film 3e by means of the first injection step, and, as shown in FIG. 13(d), the source region 1a and the drain region 1c of the TFT 30 are formed in the semiconductor film 3e by means of the second injection step. At the same time, the second injection amount of the impurity is injected into the semiconductor film 3d, thereby forming the lower capacitor electrode.

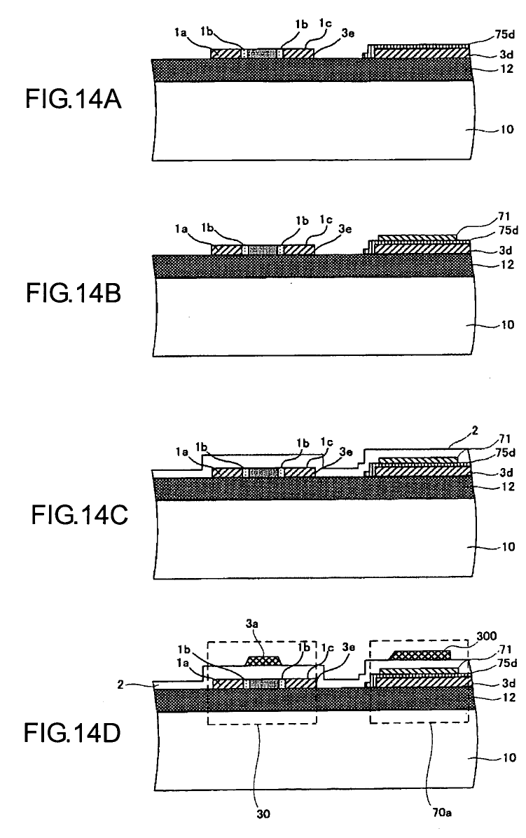

Next, in FIG. 14(a), the dummy film 75 is patterned, for example, using the photolithography method, such that the dummy film 75 is partially removed to expose the semiconductor film 3e of the TFT 30. Further, the dummy film 75 is left on the semiconductor film 3d constituting the lower capacitor electrode of the storage capacitor 70a. The second dielectric film 75d is formed with the dummy film left on the semiconductor film 3d constituting the lower capacitor electrode.

Subsequently, in FIG. 14(b), the stack electrode 71 is formed on the second dielectric film 75d, and, in FIG. 14(c), the gate insulating film 2 is formed. Next, in FIG. 14(d), the gate electrode 3a, the capacitor electrode 300, and the scanning line 11a which is not shown in FIG. 14(d) are formed. As a result, the stacked storage capacitor 70a is formed, together with the TFT 30.

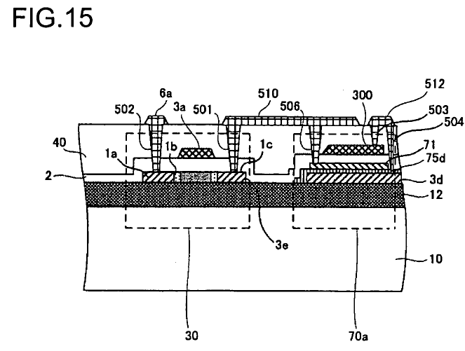

Next, in FIG. 15, the first interlayer insulating film 40 is formed, and the contact holes 501, 502, 503, 504 and 506 are respectively opened. And then, the contact holes 501, 502, 503, 504 and 506 are respectively filled with a conductive material, thereby forming the data line 6a, the drain electrode 510, and the connecting electrode 512.

<2-1: Modification>

A modification of the second embodiment described above will be described with reference to FIGS. 13, 14 and 16.

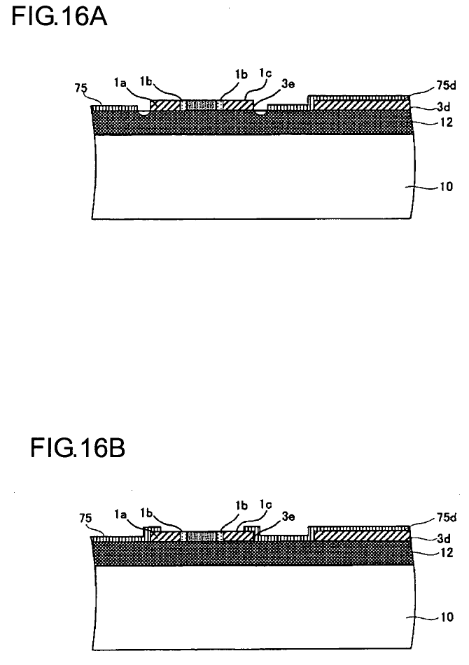

FIGS. 16(a) and 16(b) shows a cross-sectional configuration of the TFT array substrate 10 in the step of removing the dummy film which is described with reference to FIG. 14(a).

In FIG. 13(b), the dummy film 75 may be made of the same film as that of the base insulating film 12, for example, the silicon oxide film. The silicon oxide film is formed by means of the PE-CVD method in which, for example, a TEOS gas is used as a raw gas. At this time, by controlling the forming conditions of the dummy film 75 such as a pressure of the source gas or the like, it is preferable to control the etching rate at the time when the dummy film 75 is removed.

In the case in which the dummy film 75 is formed with a film having the etching rate different from that of the base insulating film 12, it is possible to take an etching selection ratio of the dummy film 75 and the base insulating film 12. Thus, in FIG. 16(a), it is possible to prevent the base insulating film 12 from being removed to an extent that the surface of the TFT array substrate 10 is exposed. Therefore, it is possible to easily remove the dummy film 75 in part such that the semiconductor film 3e of the TFT 30 is exposed.

Meanwhile, in the case in which the dummy film 75 is formed with a film having the etching rate equal to that of the base insulating film 2, as shown in FIG. 16(b), the dummy film 75 is patterned and partially removed such that a portion of the channel region, the lightly doped regions 1b, the source region 1a, and the drain region 1c on the surface of the semiconductor 3e is exposed. As a result, in addition to the dummy film 75 serving as the second dielectric film 75d, the dummy film 75 is also left on the surface of the semiconductor film 3e.

Moreover, the dummy film 75 is not limited to the silicon oxide film or the silicon nitride film. It is only necessary for the dummy film 75 not to contaminate the semiconductor film 3.

Further, as the storage capacitor formed according to the present invention, the storage capacitors 70 and 70a which are provided within the pixel are exemplified. However, the present invention can be similarly applied to a storage capacitor which is provided within the data line driving circuit 101 or the scanning line driving circuit 104 as a circuit element.

### <3: Electronic Apparatus>

Next, examples in which liquid crystal devices such as the above-mentioned electro-optical devices are applied to various electronic apparatuses will be described.

<3-1: Projector>

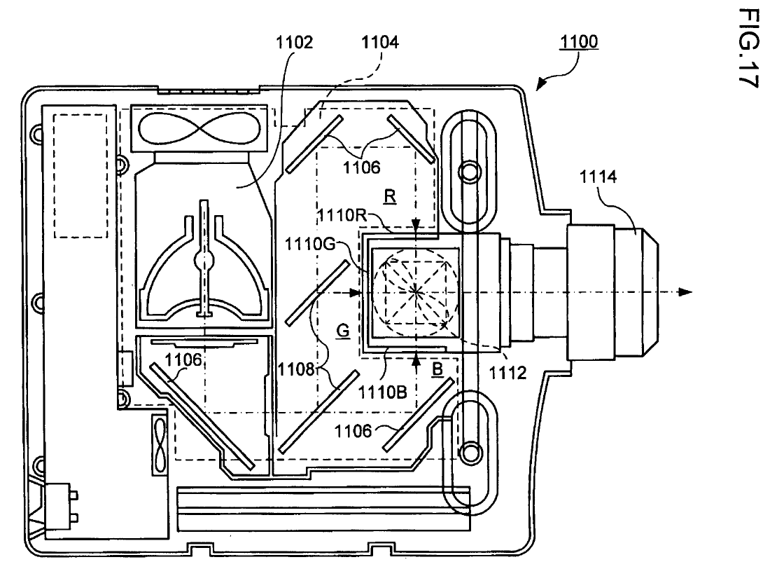

First, a projector in which the liquid crystal device is used as a light valve will be described. FIG. 17 is a plan view showing an example of a configuration of a projector. As shown in FIG. 17, within the projector 1100, a lamp unit 1102 which comprises white light sources such as halogen lamps is provided. Light emitted from the lamp unit 1102 is separated into light components of three primary color of RGB by means of four mirrors 1106 arranged within a light guide 1104 and two dichroic mirrors 1108. The light components are respectively incident to liquid crystal panels 1110R, 1110B and 1110G which serve as light valves corresponding to the respective primary colors.

The configurations of the liquid crystal panels 1110R, 1110B and 1110G are the same as that of the above-mentioned liquid crystal device. The liquid crystal panels 1110R, 1110B and 111G are driven by means of the respective primary color signals of R, G and B which are supplied from an image signal processing circuit. And then, light components modulated by the liquid crystal panels are incident to a dichroic prism 1112 in three directions. In the dichroic prism 1112, the light components of R and B are refracted by 90 degrees, and the light component of G goes straight ahead. Therefore, images of the respective colors are synthesized, such that a color image is projected on a screen via a projective lens 1114.

Here, referring to display images by means of the respective liquid crystal panels 1110R, 1110B and 1110G, the display image of the liquid crystal panel 1110G is needed to be inverted from side to side with respect to the display images by means of the liquid crystal panels 1110R and 1110B.

Moreover, since the light components corresponding to the respective primary colors of R, G and B are incident to the liquid crystal panels 1110R, 1110B and 1110G by means of the dichroic mirror 1108, there is no need to provide a color filter.

<3-2: Mobile Computer>

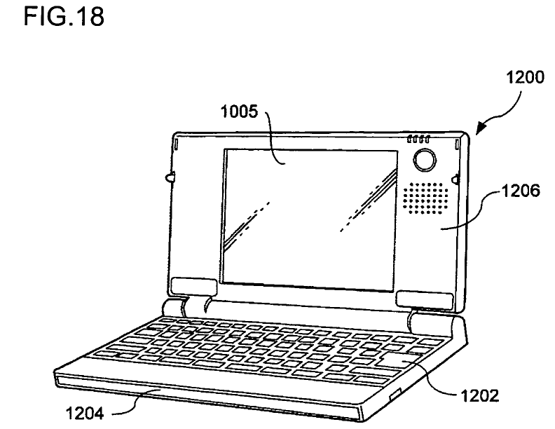

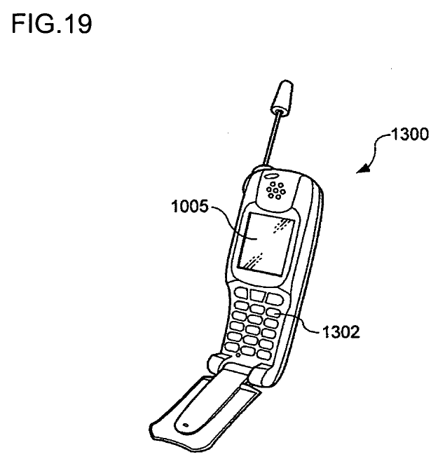

Next, an example in which the liquid crystal device is applied to a mobile personal computer will be described. FIG. 18 is a perspective view showing a configuration of the personal computer. In FIG. 18, the computer 1200 comprises a main body 1204 having a keyboard 1202, and a liquid crystal display unit 1206. The liquid crystal display unit 1206 is made by adding a backlight to the rear surface of the above-mentioned liquid crystal device 1005.

<3-3: Cellular Phone>

In addition, an example in which a liquid crystal device is applied to a cellular phone will be described. FIG. 19 is a perspective view showing a configuration of the cellular phone. In FIG. 19, the cellular phone 1300 has a plurality of operating buttons 1302 and a reflective liquid crystal device 1005. With respect to the reflective liquid crystal device 1005, if necessary, a front light is provided in a front surface thereof.

Moreover, in addition to the electronic apparatuses described with reference to FIGS. 17 to 19, a liquid crystal television, a view finder type or monitor-direct-view type video tape recorder, a car navigation device, a pager, an electronic organizer, an electronic calculator, a word processor, a workstation, a videophone, a POS terminal, a device having a touch panel or the like may be exemplified. And then, it is needless to say that the present invention can be applied to these electronic apparatuses.

The present invention is not limited to the above-mentioned embodiments, but various modifications can be made within a scope without departing from a spirit or an idea of the present invention read on the claims and the specification. An electro-optical device, a method of manufacturing the same, and an electronic apparatus having the electro-optical device are also included in a technical scope of the present invention.

1. A method of manufacturing an electro-optical device, comprising:
a step of forming a semiconductor film of a thin film transistor on a base;
a step of forming a dummy film to cover the surface of the semiconductor film;
a first injection step of injecting a first injection amount of an impurity into the semiconductor film via the dummy film to form a lightly doped region adjacent to a channel region of the thin film transistor;
a second injection step of injecting a second injection amount, more than the first injection amount, of an impurity into the semiconductor film via the dummy film to form a source region and a drain region of the thin film transistor adjacent to the lightly doped region;
a step of removing the dummy film to expose at least a portion of the channel region, the lightly doped region, the source region, and the drain region;
a step of forming a gate insulating film to cover at least the surface of the exposed portion of the semiconductor film, from which the dummy film is removed; and
a step of forming a gate electrode of the thin film transistor to overlap at least a portion of the channel region and the lightly doped region on the gate insulating film.

2. The method of manufacturing an electro-optical device according to claim 1,
wherein, in the step of forming the semiconductor film, a low-temperature polysilicon film is formed as the semiconductor film.

3. The method of manufacturing an electro-optical device according to claim 2, further comprising:
a step of patterning the semiconductor film to form a precursor film of a lower capacitor electrode of a storage capacitor;
a step of forming a first dielectric film of the storage capacitor on the lower capacitor electrode with the same material as that of the gate insulating film; and
a step of forming an upper capacitor electrode of the storage capacitor on the first dielectric film with the same material as that of the gate electrode,
wherein the second injection step is further performed on the precursor film.

4. The method of manufacturing an electro-optical device according to claim 3, further comprising:
a step of forming a second dielectric film of the storage capacitor on the precursor film with the same material as that of the dummy film; and
a step of forming a stack electrode of the storage capacitor on the second dielectric film,
wherein the second injection step is further performed on the precursor film via the second dielectric film, and
in the step of the forming the first dielectric film, the first dielectric film is formed on the stack electrode.

5. The method of manufacturing an electro-optical device according to claim 1,
wherein, in the step of forming the dummy film, the dummy film is formed to have the same etching rate as that of the base.

6. The method of manufacturing an electro-optical device according to claim 1,
wherein, in the step of forming the dummy film, the dummy film is formed to have an etching rate different from the base.

7. The method of manufacturing an electro-optical device according to claim 6,
wherein the dummy film is formed to have an etching rate larger than that of the base.

8. The method of manufacturing an electro-optical device according to claim 7,
wherein the dummy film is formed with a silicon nitride film.

9. The method of manufacturing an electro-optical device according to claim 5,
wherein the dummy film is formed with the same material as that of a film which is included in the base.

10. The method of manufacturing an electro-optical device according to claim 1,
wherein the first injection step and the second injection step are performed with an n-type impurity.

11. The method of manufacturing an electro-optical device according to claim 1,
wherein the first injection step and the second injection step are performed with a p-type impurity.

12. An electro-optical device which is manufactured by a method of manufacturing an electro-optical device as claimed in claim 1, comprising:
display elements which are arranged in a predetermined pattern in an image display region on a base and which are respectively driven in an active manner by means of thin film transistors.

13. An electronic apparatus having an electro-optical device as claimed in claim 12.
